(19) United States
(12) Patent Application Publication
(10) Pub. No.: US 2012/0161120 A1
(43) Pub. Date: Jun. 28, 2012

(54) COMPOSITIONS OF ELECTRICALLY CONDUCTING POLYMERS MADE WITH ULTRA-PURE FULLY-FLUORINATED ACID POLYMERS

(75) Inventors: Che-Hsiung Hsu, Clemmons, NC (US); Mark T. Martello, St. Paul, MN (US); Hjalti Skulason, Buellton, CA (US)

(73) Assignee: E. I. DU PONT DE NEMOURS AND COMPANY DUPONT DISPLAY INC, Wilmington, DE (US)

(21) Appl. No.: 13/416,316

(22) Filed: Mar. 9, 2012

Related U.S. Application Data
(63) Continuation of application No. 11/960,381, filed on Dec. 19, 2007.
(60) Provisional application No. 60/877,882, filed on Dec. 29, 2006.

(51) Int. Cl. H01L 51/54; H01B 1/12

(52) U.S. Cl. 257/40; 252/500; 257/E51.024

(57) ABSTRACT

There is provided an electrically conductive polymer composition. The composition contains an electrically conductive polymer made with an ultra-pure fully-fluorinated acid polymer.

### RELATED APPLICATION DATA

This application claims priority under 35 U.S.C. §119(e) from U.S. Provisional Application No. 60/877,882 filed on Dec. 29, 2006 which is incorporated by reference as if fully set forth herein.

### BACKGROUND INFORMATION

1. Field of the Disclosure

This disclosure relates in general to electrically conductive polymer compositions made with ultra-pure fully-fluorinated acid polymers, and the use of these compositions in organic electronic devices.

2. Description of the Related Art

Organic electronic devices define a category of products that include an active layer. Such devices convert electrical energy into radiation, detect signals through electronic processes, convert radiation into electrical energy, or include one or more organic semiconductor layers.

Organic light-emitting diodes (OLEDs) are organic electronic devices comprising an organic layer capable of electroluminescence. OLEDs can have the following configuration:
anode/buffer layer/EL material/cathode
   The anode is typically any material that is transparent and has the ability to inject holes into the EL material, such as, for example, indium/tin oxide (ITO). The anode is optionally supported on a glass or plastic substrate. EL materials include fluorescent compounds, fluorescent and phosphorescent metal complexes, conjugated polymers, and mixtures thereof. The cathode is typically any material (such as, e.g., Ca or Ba) that has the ability to inject electrons into the EL material. The buffer layer is typically an electrically conducting polymer and facilitates the injection of holes from the anode into the EL material layer. The buffer layer may also have other properties which facilitate device performance.

There is a continuing need for buffer materials with improved properties.

### SUMMARY

There is provided an electrically conductive polymer composition comprising an electrically conductive polymer made with an ultra-pure fully-fluorinated acid polymer.

In another embodiment, there is provided an aqueous dispersion of an electrically conductive polymer made with an ultra-pure fully-fluorinated acid polymer.

In another embodiment, electronic devices comprising at least one layer comprising the new conductive polymer composition are provided.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes a diagram illustrating contact angle.

FIG. 2 includes a schematic diagram of an electronic device.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by the Conductive Polymer, the Ultra-Pure Fully-fluorinated Acid Polymer, Preparation of the Electrically Conductive Polymer Composition with Ultra-Pure FFAP, Electronic Devices, and finally, Examples.

### 1. Definitions and Clarification of Terms Used in the Specification and Claims

Before addressing details of embodiments described below, some terms are defined or clarified.

As used herein, the term “volatile organic compound” is abbreviated as VOC and is intended to mean any organic compound having a vapor pressure greater than 2 torr (0.27 kPa) at 25° C. In some embodiments, VOCs are low molecular weight alcohols and/or ethers.

The term “ultra-pure” as it applies to a material, is intended to mean that the material has less than 0.05% by weight VOC.

The term “conductor” and its variants are intended to refer to a layer material, member, or structure having an electrical property such that current flows through such layer material, member, or structure without a substantial drop in potential. The term is intended to include semiconductors. In one embodiment, a conductor will form a layer having a conductivity of at least 10⁻⁷ S/cm.

The term “electrically conductive material” refers to a material which is inherently or intrinsically capable of electrical conductivity without the addition of carbon black or conductive metal particles.

The term “buffer layer” or “buffer material” is intended to mean electrically conductive or semiconductive materials and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. Buffer materials may be polymers, oligomers, or small molecules, and may be in the form of solutions, dispersions, suspensions, emulsions, colloidal mixtures, or other compositions.

“Hole transport” when referring to a layer, material, member, or structure, is intended to mean such layer, material, member, or structure facilitates migration of positive charges through the thickness of such layer, material, member, or structure with relative efficiency and small loss of charge. As used herein, the term “hole transport layer” does not encompass a light-emitting layer, even though that layer may have some hole transport properties.

The term “polymer” is intended to mean a material having at least one repeating monomeric unit. The term includes homopolymers having only one kind, or species, of monomeric unit, and copolymers having two or more different monomeric units, including copolymers formed from monomeric units of different species.

The term “fully-fluorinated acid polymer” refers to a polymer having acidic groups, where all of the available hydrogens have been replaced by fluorine.

The term “acidic group” refers to a group capable of ionizing to donate a hydrogen ion to a Brønsted base.

The composition may comprise one or more different electrically conductive polymers and one or more different fully-fluorinated acid polymers.

The term “doped” as it refers to an electrically conductive polymer, is intended to mean that the electrically conductive polymer has a polymeric counterion to balance the charge on the conductive polymer.

The term “doped conductive polymer” is intended to mean the conductive polymer and the polymeric counterion that is associated with it.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, lighting source, photodetector, photovoltaic, and semiconductive member arts.

### 2. Conductive Polymer

In one embodiment, the conductive polymer will form a film which has a conductivity of at least 10⁻⁷ S/cm. The monomer from which the conductive polymer is formed, is referred to as a “precursor monomer”. A copolymer will have more than one precursor monomer.

In one embodiment, the conductive polymer is made from at least one precursor monomer selected from thiophenes, selenophenes, tellurophenes, pyrroles, anilines, and polycyclic aromatics. The polymers made from these monomers are referred to herein as polythiophenes, poly(selenophenes), poly(tellurophenes), polypyrroles, polyanilines, and polycyclic aromatic polymers, respectively. The term “polycyclic aromatic” refers to compounds having more than one aromatic ring. The rings may be joined by one or more bonds, or they may be fused together. The term “aromatic ring” is intended to include heteroaromatic rings. A “polycyclic heteroaromatic” compound has at least one heteroaromatic ring. In one embodiment, the polycyclic aromatic polymers are poly(thienothiophenes).

In one embodiment, monomers contemplated for use to form the electrically conductive polymer in the new composition comprise Formula I below:

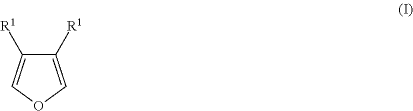

wherein:
Q is selected from the group consisting of S, Se, and Te;
R¹ is independently selected so as to be the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, alcohol, benzyl, carboxylate, ether, ether carboxylate, amidosulfonate, ether sulfonate, ester sulfonate, and urethane; or both R¹ groups together may form an alkylene or alkenylene chain completing a 3, 4, 5, 6, or 7-membered aromatic or alicyclic ring, which ring may optionally include one or more divalent nitrogen, selenium, tellurium, sulfur or oxygen atoms.

As used herein, the term “alkyl” refers to a group derived from an aliphatic hydrocarbon and includes linear, branched and cyclic groups which may be unsubstituted or substituted. The term “heteroalkyl” is intended to mean an alkyl group, wherein one or more of the carbon atoms within the alkyl group has been replaced by another atom, such as nitrogen, oxygen, sulfur, and the like. The term “alkylene” refers to an alkyl group having two points of attachment.

As used herein, the term “alkenyl” refers to a group derived from an aliphatic hydrocarbon having at least one carbon-carbon double bond, and includes linear, branched and cyclic groups which may be unsubstituted or substituted. The term “heteroalkenyl” is intended to mean an alkenyl group, wherein one or more of the carbon atoms within the alkenyl group has been replaced by another atom, such as nitrogen, oxygen, sulfur, and the like. The term “alkenylene” refers to an alkenyl group having two points of attachment.

As used herein, the following terms for substituent groups refer to the formulae given below:
“alcohol” —R³—OH
“amido” —R³—C(O)N(R⁶)R⁶
“amidosulfonate” —R³—C(O)N(R⁶)R⁴—SO₃Z
“benzyl” —CH₂—C₆H₅
“carboxylate” —R³—C(O)O—Z or —R³—O—C(O)—Z
“ether” —R³—(O—R⁵)ₚ—O—R⁵
“ether carboxylate” —R³—O—R⁴—C(O)O—Z or —R³—O—R⁴—O—C(O)—Z
“ether sulfonate” —R³—O—R⁴—SO₃Z
“ester sulfonate” —R³—O—C(O)—R⁴—SO₃Z
“sulfonimide” —R³—SO₂—NH—SO₂—R⁵
“urethane” —R³—O—C(O)—N(R⁶)₂
where all “R” groups are the same or different at each occurrence and:
   R³ is a single bond or an alkylene group
   R⁴ is an alkylene group
   R⁵ is an alkyl group
   R⁶ is hydrogen or an alkyl group
   p is 0 or an integer from 1 to 20
   Z is H, alkali metal, alkaline earth metal, N(R⁵)₄ or R⁵
      Any of the above groups may further be unsubstituted or substituted, and any group may have F substituted for one or more hydrogens, including perfluorinated groups. In one embodiment, the alkyl and alkylene groups have from 1-20 carbon atoms.

In one embodiment, in the monomer, both R¹ together form —O—(CHY)ₘ—O—, where m is 2 or 3, and Y is the same or different at each occurrence and is selected from hydrogen, halogen, alkyl, alcohol, amidosulfonate, benzyl, carboxylate, ether, ether carboxylate, ether sulfonate, ester sulfonate, and urethane, where the Y groups may be partially or fully fluorinated. In one embodiment, all Y are hydrogen. In one embodiment, the polymer is poly(3,4-ethylenedioxythiophene). In one embodiment, at least one Y group is not hydrogen. In one embodiment, at least one Y group is a substituent having F substituted for at least one hydrogen. In one embodiment, at least one Y group is perfluorinated.

In one embodiment, the monomer has Formula I(a):

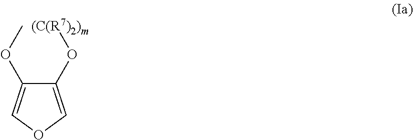

wherein:
Q is selected from the group consisting of S, Se, and Te;
R⁷ is the same or different at each occurrence and is selected from hydrogen, alkyl, heteroalkyl, alkenyl, heteroalkenyl, alcohol, amidosulfonate, benzyl, carboxylate, ether, ether carboxylate, ether sulfonate, ester sulfonate, and urethane, with the proviso that at least one R⁷ is not hydrogen, and
m is 2 or 3.

In one embodiment of Formula I(a), m is two, one R⁷ is an alkyl group of more than 5 carbon atoms, and all other R⁷ are hydrogen. In one embodiment of Formula I(a), at least one R⁷ group is fluorinated. In one embodiment, at least one R⁷ group has at least one fluorine substituent. In one embodiment, the R⁷ group is fully fluorinated.

In one embodiment of Formula I(a), the R⁷ substituents on the fused alicyclic ring on the monomer offer improved solubility of the monomers in water and facilitate polymerization in the presence of the fluorinated acid polymer.

In one embodiment of Formula I(a), m is 2, one R⁷ is sulfonic acid-propylene-ether-methylene and all other R⁷ are hydrogen. In one embodiment, m is 2, one R⁷ is propyl-ether-ethylene and all other R⁷ are hydrogen. In one embodiment, m is 2, one R⁷ is methoxy and all other R⁷ are hydrogen. In one embodiment, one R⁷ is sulfonic acid difluoromethylene ester methylene (—CH₂—O—C(O)—CF₂—SO₃H), and all other R⁷ are hydrogen.

In one embodiment, pyrrole monomers contemplated for use to form the electrically conductive polymer in the new composition comprise Formula II below.

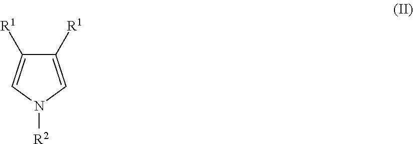

where in Formula II:
R¹ is independently selected so as to be the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, alcohol, benzyl, carboxylate, ether, amidosulfonate, ether carboxylate, ether sulfonate, ester sulfonate, and urethane; or both R¹ groups together may form an alkylene or alkenylene chain completing a 3, 4, 5, 6, or 7-membered aromatic or alicyclic ring, which ring may optionally include one or more divalent nitrogen, sulfur, selenium, tellurium, or oxygen atoms; and
R² is independently selected so as to be the same or different at each occurrence and is selected from hydrogen, alkyl, alkenyl, aryl, alkanoyl, alkylthioalkyl, alkylaryl, arylalkyl, amino, epoxy, silane, siloxane, alcohol, benzyl, carboxylate, ether, ether carboxylate, ether sulfonate, ester sulfonate, and urethane.

In one embodiment, R¹ is the same or different at each occurrence and is independently selected from hydrogen, alkyl, alkenyl, alkoxy, cycloalkyl, cycloalkenyl, alcohol, benzyl, carboxylate, ether, amidosulfonate, ether carboxylate, ether sulfonate, ester sulfonate, urethane, epoxy, silane, siloxane, and alkyl substituted with one or more of sulfonic acid, carboxylic acid, acrylic acid, phosphoric acid, phosphonic acid, halogen, nitro, cyano, hydroxyl, epoxy, silane, or siloxane moieties.

In one embodiment, R² is selected from hydrogen, alkyl, and alkyl substituted with one or more of sulfonic acid, carboxylic acid, acrylic acid, phosphoric acid, phosphonic acid, halogen, cyano, hydroxyl, epoxy, silane, or siloxane moieties.

In one embodiment, the pyrrole monomer is unsubstituted and both R¹ and R² are hydrogen.

In one embodiment, both R¹ together form a 6- or 7-membered alicyclic ring, which is further substituted with a group selected from alkyl, heteroalkyl, alcohol, benzyl, carboxylate, ether, ether carboxylate, ether sulfonate, ester sulfonate, and urethane. These groups can improve the solubility of the monomer and the resulting polymer. In one embodiment, both R¹ together form a 6- or 7-membered alicyclic ring, which is further substituted with an alkyl group. In one embodiment, both R¹ together form a 6- or 7-membered alicyclic ring, which is further substituted with an alkyl group having at least 1 carbon atom.

In one embodiment, both R¹ together form —O—(CHY)ₘ—O—, where m is 2 or 3, and Y is the same or different at each occurrence and is selected from hydrogen, alkyl, alcohol, benzyl, carboxylate, amidosulfonate, ether, ether carboxylate, ether sulfonate, ester sulfonate, and urethane. In one embodiment, at least one Y group is not hydrogen. In one embodiment, at least one Y group is a substituent having F substituted for at least one hydrogen. In one embodiment, at least one Y group is perfluorinated.

In one embodiment, aniline monomers contemplated for use to form the electrically conductive polymer in the new composition comprise Formula III below.

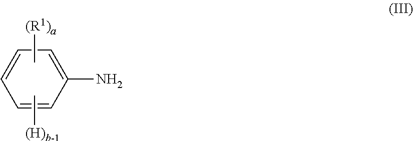

wherein:

a is 0 or an integer from 1 to 4;

b is an integer from 1 to 5, with the proviso that a+b=5; and R¹ is independently selected so as to be the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, cyano, hydroxyl, epoxy, silane, siloxane, alcohol, benzyl, carboxylate, ether, ether carboxylate, amidosulfonate, ether sulfonate, ester sulfonate, and urethane; or both R¹ groups together may form an alkylene or alkenylene chain completing a 3, 4, 5, 6, or 7-membered aromatic or alicyclic ring, which ring may optionally include one or more divalent nitrogen, sulfur or oxygen atoms.

When polymerized, the aniline monomeric unit can have Formula IV(a) or Formula IV(b) shown below, or a combination of both formulae.

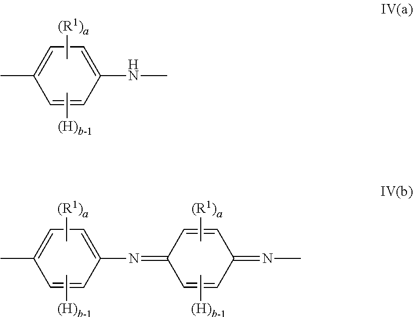

where a, b and R¹ are as defined above.

In one embodiment, the aniline monomer is unsubstituted and a=0.

In one embodiment, a is not 0 and at least one R¹ is fluorinated. In one embodiment, at least one R¹ is perfluorinated.

In one embodiment, fused polycylic heteroaromatic monomers contemplated for use to form the electrically conductive polymer in the new composition have two or more fused aromatic rings, at least one of which is heteroaromatic. In one embodiment, the fused polycyclic heteroaromatic monomer has Formula V:

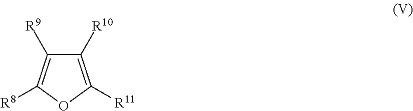

wherein:
Q is S, Se, Te, or NR⁶;
R⁶ is hydrogen or alkyl;
R⁸, R⁹, R¹⁰, and R¹¹ are independently selected so as to be the same or different at each occurrence and are selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, nitrile, cyano, hydroxyl, epoxy, silane, siloxane, alcohol, benzyl, carboxylate, ether, ether carboxylate, amidosulfonate, ether sulfonate, ester sulfonate, and urethane; and
at least one of R⁸ and R⁹, R⁹ and R¹⁰, and R¹⁰ and R¹¹ together form an alkenylene chain completing a 5 or 6-membered aromatic ring, which ring may optionally include one or more divalent nitrogen, sulfur,selenium, tellurium, or oxygen atoms.

In one embodiment, the fused polycyclic heteroaromatic monomer has Formula V(a), V(b), V(c), V(d), V(e), V(f), and V(g):

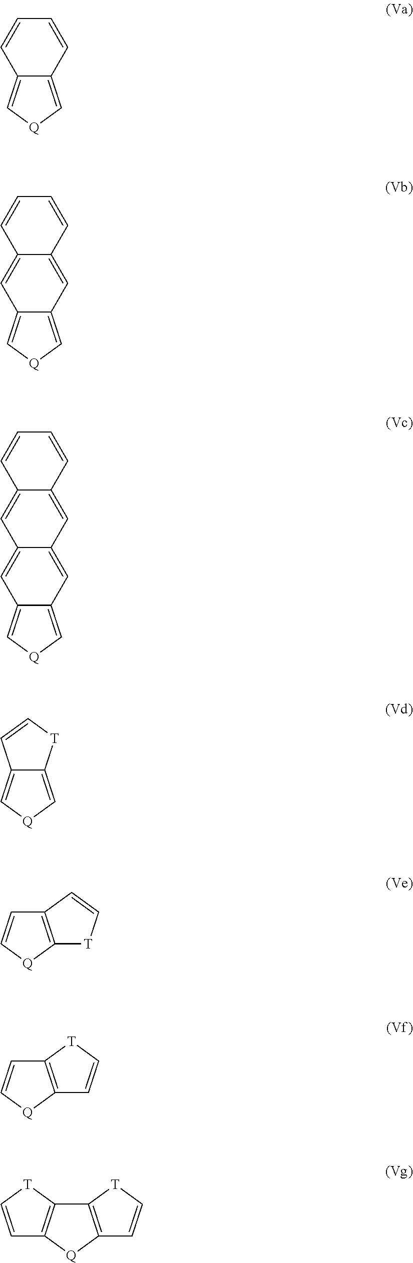

wherein:
Q is S, Se, Te, or NH; and
T is the same or different at each occurrence and is selected from S, NR⁶, O, SiR⁶₂, Se, Te, and PR⁶;
R⁶ is hydrogen or alkyl.
   The fused polycyclic heteroaromatic monomers may be further substituted with groups selected from alkyl, heteroalkyl, alcohol, benzyl, carboxylate, ether, ether carboxylate, ether sulfonate, ester sulfonate, and urethane. In one embodiment, the substituent groups are fluorinated. In one embodiment, the substituent groups are fully fluorinated.

In one embodiment, the fused polycyclic heteroaromatic monomer is a thieno(thiophene). Such compounds have been discussed in, for example, Macromolecules, 34, 5746-5747 (2001); and Macromolecules, 35, 7281-7286 (2002). In one embodiment, the thieno(thiophene) is selected from thieno(2,3-b)thiophene, thieno(3,2-b)thiophene, and thieno(3,4-b)thiophene. In one embodiment, the thieno(thiophene)monomer is further substituted with at least one group selected from alkyl, heteroalkyl, alcohol, benzyl, carboxylate, ether, ether carboxylate, ether sulfonate, ester sulfonate, and urethane. In one embodiment, the substituent groups are fluorinated. In one embodiment, the substituent groups are fully fluorinated.

In one embodiment, polycyclic heteroaromatic monomers contemplated for use to form the polymer in the new composition comprise Formula VI:

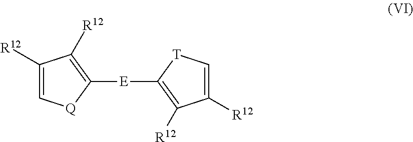

wherein:
Q is S, Se, Te, or NR⁶;
T is selected from S, NR⁶, O, SiR⁶₂, Se, Te, and PR⁶;
E is selected from alkenylene, arylene, and heteroarylene;
R⁶ is hydrogen or alkyl;
   R¹² is the same or different at each occurrence and is selected from hydrogen, alkyl, alkenyl, alkoxy, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, acrylic acid, phosphoric acid, phosphonic acid, halogen, nitro, nitrile, cyano, hydroxyl, epoxy, silane, siloxane, alcohol, benzyl, carboxylate, ether, ether carboxylate, amidosulfonate, ether sulfonate, ester sulfonate, and urethane; or both R¹² groups together may form an alkylene or alkenylene chain completing a 3, 4, 5, 6, or 7-membered aromatic or alicyclic ring, which ring may optionally include one or more divalent nitrogen, sulfur, selenium, tellurium, or oxygen atoms.

In one embodiment, the electrically conductive polymer is selected from the group consisting of thiophenes, pyrroles, thienothiophenes, and mixtures thereof.

In one embodiment, the electrically conductive polymer is a copolymer of a precursor monomer and at least one second monomer. Any type of second monomer can be used, so long as it does not detrimentally affect the desired properties of the copolymer. In one embodiment, the second monomer comprises no more than 50% of the polymer, based on the total number of monomer units. In one embodiment, the second monomer comprises no more than 30%, based on the total number of monomer units. In one embodiment, the second monomer comprises no more than 10%, based on the total number of monomer units.

Exemplary types of second monomers include, but are not limited to, alkenyl, alkynyl, arylene, and heteroarylene. Examples of second monomers include, but are not limited to, fluorene, oxadiazole, thiadiazole, benzothiadiazole, phenylenevinylene, phenyleneethynylene, pyridine, diazines, and triazines, all of which may be further substituted.

In one embodiment, the copolymers are made by first forming an intermediate precursor monomer having the structure A-B-C, where A and C represent precursor monomers, which can be the same or different, and B represents a second monomer. The A-B-C intermediate precursor monomer can be prepared using standard synthetic organic techniques, such as Yamamoto, Stille, Grignard metathesis, Suzuki, and Negishi couplings. The copolymer is then formed by oxidative polymerization of the intermediate precursor monomer alone, or with one or more additional precursor monomers.

In one embodiment, the electrically conductive polymer is a copolymer of two or more precursor monomers. In one embodiment, the precursor monomers are selected from a thiophene, a selenophene, a tellurophene, a pyrrole, and a thienothiophene.

### 3. Ultra-Pure Fully-fluorinated Acid Polymers

The ultra-pure fully-fluorinated acid polymer (“FFAP”) can be any polymer which is fully fluorinated and has acidic groups with acidic protons, and which has a VOC content of less than 0.05% by weight. The acidic groups supply an ionizable proton. In one embodiment, the acidic proton has a pKa of less than 3. In one embodiment, the acidic proton has a pKa of less than 0. In one embodiment, the acidic proton has a pKa of less than −5. The acidic group can be attached directly to the polymer backbone, or it can be attached to side chains on the polymer backbone. Examples of acidic groups include, but are not limited to, carboxylic acid groups, sulfonic acid groups, sulfonimide groups, phosphoric acid groups, phosphonic acid groups, and combinations thereof. The acidic groups can all be the same, or the polymer may have more than one type of acidic group. In one embodiment, the acidic groups are selected from the group consisting of sulfonic acid groups, sulfonimide groups, and combinations thereof.

In one embodiment, the FFAP is water-soluble. In one embodiment, the FFAP is dispersible in water.

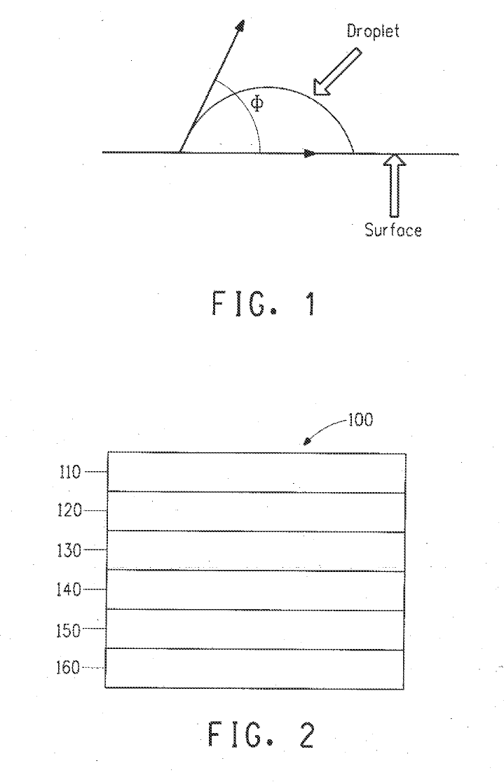

In one embodiment, the FFAP is organic solvent wettable. The term “organic solvent wettable” refers to a material which, when formed into a film, is wettable by organic solvents. In one embodiment, wettable materials form films which are wettable by phenylhexane with a contact angle no greater than 40°. As used herein, the term “contact angle” is intended to mean the angle φ shown in FIG. 1. For a droplet of liquid medium, angle φ is defined by the intersection of the plane of the surface and a line from the outer edge of the droplet to the surface. Furthermore, angle φ is measured after the droplet has reached an equilibrium position on the surface after being applied, i.e. “static contact angle”. The film of the organic solvent wettable fluorinated polymeric acid is represented as the surface. In one embodiment, the contact angle is no greater than 35°. In one embodiment, the contact angle is no greater than 30°. The methods for measuring contact angles are well known.

Examples of suitable polymeric backbones include, but are not limited to, polyolefins, polyacrylates, polymethacrylates, polyimides, polyamides, polyaramids, polyacrylamides, polystyrenes, and copolymers thereof, all of which are fully fluorinated.

In one embodiment, the acidic groups are sulfonic acid groups or sulfonimide groups. A sulfonimide group has the formula:

—SO₂—NH—SO₂—R

where R is an alkyl group.

In one embodiment, the acidic groups are on a fluorinated side chain. In one embodiment, the fluorinated side chains are selected from alkyl groups, alkoxy groups, amido groups, ether groups, and combinations thereof, all of which are fully fluorinated.

In one embodiment, the FFAP has a perfluorinated olefin backbone, with pendant perfluorinated alkyl sulfonate, perfluorinated ether sulfonate, perfluorinated ester sulfonate, or perfluorinated ether sulfonimide groups. In one embodiment, the FFAP is a perfluoroolefin having perfluoro-ether-sulfonic acid side chains. In one embodiment, the polymer is a copolymer of 1,1-difluoroethylene and 2-(1,1-difluoro-2-(trifluoromethyl)allyloxy)-1,1,2,2-tetrafluoroethanesulfonic acid. In one embodiment, the polymer is a copolymer of ethylene and 2-(2-(1,2,2-trifluorovinyloxy)-1,1,2,3,3,3-hexafluoropropoxy)-1,1,2,2-tetrafluoroethanesulfonic acid. These copolymers can be made as the corresponding sulfonyl fluoride polymer and then can be converted to the sulfonic acid form.

In one embodiment, the FFAP is homopolymer or copolymer of a fluorinated and partially sulfonated poly(arylene ether sulfone). The copolymer can be a block copolymer.

In one embodiment, the FFAP is a sulfonimide polymer having Formula IX:

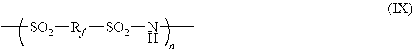

where:
R_{f} is selected from perfluorinated alkylene, perfluorinated heteroalkylene, perfluorinated arylene, and perfluorinated heteroarylene, which may be substituted with one or more ether oxygens; and
n is at least 4.
   In one embodiment of Formula IX, R_{f} is a perfluoroalkyl group. In one embodiment, R_{f} is a perfluorobutyl group. In one embodiment, R_{f} contains ether oxygens. In one embodiment n is greater than 10.

In one embodiment, the FFAP comprises a perfluorinated polymer backbone and a side chain having Formula X:

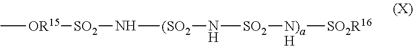

where:
R¹⁵ is a perfluorinated alkylene group or a perfluorinated heteroalkylene group;
R¹⁶ is a perfluorinated alkyl or a perfluorinated aryl group; and
a is 0 or an integer from 1 to 4.

In one embodiment, the FFAP has Formula XI:

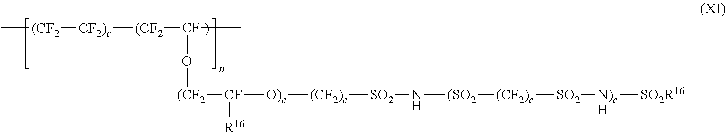

where:
R¹⁶ is a perfluorinated alkyl or a perfluorinated aryl group;
c is independently 0 or an integer from 1 to 3; and
n is at least 4.

The synthesis of FFAPs has been described in, for example, A. Feiring et al., J. Fluorine Chemistry 2000, 105, 129-135; A. Feiring et al., Macromolecules 2000, 33, 9262-9271; D. D. Desmarteau, J. Fluorine Chem. 1995, 72, 203-208; A. J. Appleby et al., J. Electrochem. Soc. 1993, 140(1), 109-111; and Desmarteau, U.S. Pat. No. 5,463,005.

In one embodiment, the FFAP also comprises a repeat unit derived from at least one perfluorinated ethylenically unsaturated compound. The perfluoroolefin comprises 2 to 20 carbon atoms. Representative perfluoroolefins include, but are not limited to, tetrafluoroethylene, hexafluoropropylene, perfluoro-(2,2-dimethyl-1,3-dioxole), perfluoro-(2-methylene-4-methyl-1,3-dioxolane), CF₂═CFO(CF₂)ₜCF═CF₂, where t is 1 or 2, and R_{f}″OCF═CF₂ wherein R_{f}″ is a saturated perfluoroalkyl group of from 1 to about ten carbon atoms. In one embodiment, the comonomer is tetrafluoroethylene.

In one embodiment, the FFAP is a colloid-forming polymeric acid. As used herein, the term “colloid-forming” refers to materials which are insoluble in water, and form colloids when dispersed into an aqueous medium. The colloid-forming polymeric acids typically have a molecular weight in the range of about 10,000 to about 4,000,000. In one embodiment, the polymeric acids have a molecular weight of about 100,000 to about 2,000,000. Colloid particle size typically ranges from 2 nanometers (nm) to about 140 nm. In one embodiment, the colloids have a particle size of 2 nm to about 30 nm. Any fully-fluorinated colloid-forming polymeric material having acidic protons can be used.

Some of the polymers described hereinabove may be formed in non-acid form, e.g., as salts, esters, or sulfonyl fluorides. They will be converted to the acid form for the preparation of conductive compositions, described below.

In some embodiments, the ultra-pure FFAP is prepared using a procedure similar to the procedure in U.S. Pat. No. 6,150,426, Example 1, Part 2. The temperature is approximately 270° C., and the material is diluted with water having no detectable VOC content.

4. Preparation of the Electrically Conductive Polymer Composition with Ultra-Pure FFAP

In one embodiment, the doped electrically conductive polymer composition is formed by the oxidative polymerization of the precursor monomers in the presence of an ultra-pure FFAP. In one embodiment, the precursor monomers comprise two or more conductive precursor monomers. In one embodiment, the monomers comprise an intermediate precursor monomer having the structure A-B-C, where A and C represent conductive precursor monomers, which can be the same or different, and B represents a non-conductive precursor monomer. In one embodiment, the intermediate precursor monomer is polymerized with one or more conductive precursor monomers.

In one embodiment, the oxidative polymerization is carried out in a homogeneous water solution. Oxidizing agents such as ammonium persulfate, sodium persulfate, potassium persulfate, and the like, can be used. A catalyst, such as ferric chloride, or ferric sulfate may also be present. The resulting polymerized product will be a solution, dispersion, or emulsion of the conductive polymer in association with the FFAP. In one embodiment, the intrinsically conductive polymer is positively charged, and the charges are balanced by the FFAP anion.

In one embodiment, the method of making an aqueous dispersion of the new conductive polymer composition includes forming a reaction mixture by combining water, precursor monomer, at least one ultra-pure FFAP, and an oxidizing agent, in any order, provided that at least a portion of the ultra-pure FFAP is present when at least one of the precursor monomer and the oxidizing agent is added.

In one embodiment, the method of making the doped conductive polymer composition comprises:
(a) providing an aqueous solution or dispersion of a ultra-pure FFAP;
(b) adding an oxidizer to the solutions or dispersion of step (a); and
(c) adding precursor monomer to the mixture of step (b).

In another embodiment, the precursor monomer is added to the aqueous solution or dispersion of the FFAP prior to adding the oxidizer. Step (b) above, which is adding oxidizing agent, is then carried out.

In another embodiment, a mixture of water and the precursor monomer is formed, in a concentration typically in the range of about 0.5% by weight to about 4.0% by weight total precursor monomer. This precursor monomer mixture is added to the aqueous solution or dispersion of the ultra-pure FFAP, and steps (b) above which is adding oxidizing agent is carried out.

In another embodiment, the aqueous polymerization mixture may include a polymerization catalyst, such as ferric sulfate, ferric chloride, and the like. The catalyst is added before the last step. In another embodiment, a catalyst is added together with an oxidizing agent.

In one embodiment, the polymerization is carried out in the presence of a co-acid which is a Brønsted acid. The acid can be an inorganic acid, such as HCl, sulfuric acid, and the like, or an organic acid, such as acetic acid or p-toluenesulfonic acid. Alternatively, the acid can be a water soluble polymeric acid such as poly(styrenesulfonic acid), poly(2-acrylamido-2-methyl-1-propanesulfonic acid, or the like, or a second ultra-pure FFAP, as described above. Combinations of acids can be used.

The co-acid can be added to the reaction mixture at any point in the process prior to the addition of either the oxidizer or the precursor monomer, whichever is added last. In one embodiment, the co-acid is added before both the precursor monomers and the ultra-pure FFAP, and the oxidizer is added last. In one embodiment the co-acid is added prior to the addition of the precursor monomers, followed by the addition of the ultra-pure FFAP, and the oxidizer is added last.

In one embodiment, a reaction vessel is charged first with a mixture of water and inorganic co-acid. To this is added, in order, the precursor monomers, an aqueous solution or dispersion of ultra-pure FFAP, and an oxidizer. The oxidizer is added slowly and dropwise to prevent the formation of localized areas of high ion concentration which can destabilize the mixture. The mixture is stirred and the reaction is then allowed to proceed at a controlled temperature. When polymerization is completed, the reaction mixture is treated with a strong acid cation resin, stirred and filtered; and then treated with a base anion exchange resin, stirred and filtered. Alternative orders of addition can be used, as discussed above.

In some embodiments, the oxidizing agent and the precursor monomer are added simultaneously to an aqueous solution or dispersion of the ultra-pure FFAP and catalyst, at a slow rate.

In some embodiments, the precursor monomer is injected rapidly into an aqueous solution or dispersion containing ultra-pure FFAP, catalyst and oxidizer.

In all cases, care must be taken to insure that the reactants are ultra-pure with respect to VOC content.

In the method of making the new conductive polymer composition, the molar ratio of oxidizer to total precursor monomer is generally in the range of 0.1 to 2.0; and in one embodiment is 0.4 to 1.5. The molar ratio of ultra-pure FFAP to total precursor monomer is generally in the range of 0.3 to 10. In one embodiment, the ratio is in the range of 1 to 7. The overall solid content is generally in the range of about 0.5% to 15% in weight percentage; and in one embodiment of about 2% to 10%. The reaction temperature is generally in the range of about 4° C. to 50° C.; in one embodiment about 20° C. to 35° C.; in one embodiment about 10° C. to 25° C. The molar ratio of optional co-acid to precursor monomer is about 0.05 to 4. The reaction time is generally in the range of about 1 to about 30 hours.

### 5. Adjustment of pH

In one embodiment, the conductive polymer composition as described above, is contacted with at least one ion exchange resin under conditions suitable to replace acidic protons with cations. The composition may be treated with one or more types of ion exchange resins, simultaneously or sequentially.

Ion exchange is a reversible chemical reaction wherein an ion in a fluid medium (such as an aqueous dispersion) is exchanged for a similarly charged ion attached to an immobile solid particle that is insoluble in the fluid medium. The term “ion exchange resin” is used herein to refer to all such substances. The resin is rendered insoluble due to the crosslinked nature of the polymeric support to which the ion exchanging groups are attached. Ion exchange resins are classified as cation exchangers or anion exchangers. Cation exchangers have positively charged mobile ions available for exchange, typically metal ions such as sodium ions. Anion exchangers have exchangeable ions which are negatively charged, typically hydroxide ions.

In one embodiment, a first ion exchange resin is a cation acid exchange resin which can be in metal ion, typically sodium ion, form. A second ion exchange resin is a basic, anion exchange resin. Both acidic, cation proton exchange resins and basic, anion exchange resins can be used. In one embodiment, the acidic cation exchange resin is an inorganic acid, cation exchange resin, such as a sulfonic acid cation exchange resin. Sulfonic acid cation exchange resins contemplated for use in the practice of the invention include, for example, sulfonated styrene-divinylbenzene copolymers, sulfonated crosslinked styrene polymers, phenol-formaldehyde-sulfonic acid resins, benzene-formaldehyde-sulfonic acid resins, and mixtures thereof. In another embodiment, the acidic, cation exchange resin is an organic acid, cation exchange resin, such as carboxylic acid, acrylic or phosphorous cation exchange resin. In addition, mixtures of different cation exchange resins can be used.

In another embodiment, the basic, anionic exchange resin is a tertiary amine anion exchange resin. Tertiary amine anion exchange resins contemplated for use in the practice of the invention include, for example, tertiary-aminated styrene-divinylbenzene copolymers, tertiary-aminated crosslinked styrene polymers, tertiary-aminated phenol-formaldehyde resins, tertiary-aminated benzene-formaldehyde resins, and mixtures thereof. In a further embodiment, the basic, anionic exchange resin is a quaternary amine anion exchange resin, or mixtures of these and other exchange resins.

In one embodiment, both types of resins are added simultaneously to a liquid composition comprising the electrically conducting polymer and ultra-pure FFAP, and allowed to remain in contact with the liquid composition for at least about 1 hour, e.g., about 2 hours to about 20 hours. The ion exchange resins can then be removed from the dispersion by filtration. The size of the filter is chosen so that the relatively large ion exchange resin particles will be removed while the smaller dispersion particles will pass through. In general, about one to five grams of ion exchange resin is used per gram of new conductive polymer composition.

In some embodiments, the pH is adjusted by the addition of an aqueous basic solution. Basic compounds include hydroxides, carbonates and bicarbonates. Examples of such as a solution include, but are not limited to, sodium hydroxide, ammonium hydroxide, tetra-methylammonium hydroxide, and the like.

In one embodiment, the final pH is greater than 3; in one embodiment, greater than 4; in one embodiment, greater than 5.

### 6. Electronic Devices

In another embodiment of the invention, there are provided electronic devices comprising at least one layer made from the conductive polymer composition described herein. The term “electronic device” is intended to mean a device including one or more organic semiconductor layers or materials. An electronic device includes, but is not limited to: (1) a device that converts electrical energy into radiation (e.g., a light-emitting diode, light emitting diode display, diode laser, or lighting panel), (2) a device that detects a signal using an electronic process (e.g., a photodetector, a photoconductive cell, a photoresistor, a photoswitch, a phototransistor, a phototube, an infrared (“IR”) detector, or a biosensors), (3) a device that converts radiation into electrical energy (e.g., a photovoltaic device or solar cell), (4) a device that includes one or more electronic components that include one or more organic semiconductor layers (e.g., a transistor or diode), or any combination of devices in items (1) through (4).

In one embodiment, the electronic device comprises at least one electroactive layer positioned between two electrical contact layers, wherein the device further includes the bilayer. The term “electroactive” when referring to a layer or material is intended to mean a layer or material that exhibits electronic or electro-radiative properties. An electroactive layer material may emit radiation or exhibit a change in concentration of electron-hole pairs when receiving radiation.

As shown in FIG. 2, a typical device, 100, has an anode layer 110, a buffer layer 120, an optional hole transport layer 130, an electroactive layer 140, an optional electron-injection/transport layer 150, and a cathode layer 160.

The device may include a support or substrate (not shown) that can be adjacent to the anode layer 110 or the cathode layer 160. Most frequently, the support is adjacent the anode layer 110. The support can be flexible or rigid, organic or inorganic. Examples of support materials include, but are not limited to, glass, ceramic, metal, and plastic films.

The anode layer 110 is an electrode that is more efficient for injecting holes compared to the cathode layer 160. The anode can include materials containing a metal, mixed metal, alloy, metal oxide or mixed oxide. Suitable materials include the mixed oxides of the Group 2 elements (i.e., Be, Mg, Ca, Sr, Ba, Ra), the Group 11 elements, the elements in Groups 4, 5, and 6, and the Group 8-10 transition elements. If the anode layer 110 is to be light transmitting, mixed oxides of Groups 12, 13 and 14 elements, such as indium-tin-oxide, may be used. As used herein, the phrase “mixed oxide” refers to oxides having two or more different cations selected from the Group 2 elements or the Groups 12, 13, or 14 elements. Some non-limiting, specific examples of materials for anode layer 110 include, but are not limited to, indium-tin-oxide (“ITO”), indium-zinc-oxide, aluminum-tin-oxide, gold, silver, copper, and nickel. The anode may also comprise an organic material, especially a conducting polymer such as polyaniline, including exemplary materials as described in “Flexible light-emitting diodes made from soluble conducting polymer,” Nature vol. 357, pp 477 479 (11 Jun. 1992). At least one of the anode and cathode should be at least partially transparent to allow the generated light to be observed.

The anode layer 110 may be formed by a chemical or physical vapor deposition process or spin coating process. Chemical vapor deposition may be performed as a plasma-enhanced chemical vapor deposition (“PECVD”) or metal organic chemical vapor deposition (“MOCVD”). Physical vapor deposition can include all forms of sputtering, including ion beam sputtering, as well as e-beam evaporation and resistance evaporation. Specific forms of physical vapor deposition include rf magnetron sputtering and inductively-coupled plasma physical vapor deposition (“IMP-PVD”). These deposition techniques are well known within the semiconductor fabrication arts.

In one embodiment, the anode layer 110 is patterned during a lithographic operation. The pattern may vary as desired. The layers can be formed in a pattern by, for example, positioning a patterned mask or resist on the first flexible composite barrier structure prior to applying the first electrical contact layer material. Alternatively, the layers can be applied as an overall layer (also called blanket deposit) and subsequently patterned using, for example, a patterned resist layer and wet chemical or dry etching techniques. Other processes for patterning that are well known in the art can also be used.

The conductive polymer compositions described herein are suitable as the buffer layer 120. The term “buffer layer” or “buffer material” is intended to mean electrically conductive or semiconductive materials and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. The buffer layer is usually deposited onto substrates using a variety of techniques well-known to those skilled in the art. Typical deposition techniques include vapor deposition, liquid deposition (continuous and discontinuous techniques), and thermal transfer. Continuous deposition techniques, include but are not limited to, spin coating, gravure coating, curtain coating, dip coating, slot-die coating, spray coating, and continuous nozzle coating. Discontinuous deposition techniques include, but are not limited to, ink jet printing, gravure printing, and screen printing.

An optional layer, 130 may be present between the buffer layer 120 and the electroactive layer 140. This layer may comprise hole transport materials. Examples of hole transport materials have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); N,N′-diphenyl-N,N′-bis(3-methylphenyl)-[1,1-biphenyl]-4,4′-diamine (TPD); 1,1-bis[(di-4-tolylamino)phenyl]cyclohexane (TAPC); N,N′-bis(4-methylphenyl)-N,N′-bis(4-ethylphenyl)-[1,1-(3,3′-dimethyl)biphenyl]-4,4′-diamine (ETPD); tetrakis-(3-methylphenyl)-N,N,N′,N′-2,5-phenylenediamine (PDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate.

In some embodiments, the hole transport layer comprises a hole transport polymer. In some embodiments, the hole transport polymer is a distyrylaryl compound. In some embodiments, the aryl group is has two or more fused aromatic rings. In some embodiments, the aryl group is an acene. The term “acene” as used herein refers to a hydrocarbon parent component that contains two or more ortho-fused benzene rings in a straight linear arrangement.

In some embodiments, the hole transport polymer is an arylamine polymer. In some embodiments, it is a copolymer of fluorene and arylamine monomers.

In some embodiments, the polymer has crosslinkable groups. In some embodiments, crosslinking can be accomplished by a heat treatment and/or exposure to UV or visible radiation. Examples of crosslinkable groups include, but are not limited to vinyl, acrylate, perfluorovinylether, 1-benzo-3,4-cyclobutane, siloxane, and methyl esters. Crosslinkable polymers can have advantages in the fabrication of solution-process OLEDs. The application of a soluble polymeric material to form a layer which can be converted into an insoluble film subsequent to deposition, can allow for the fabrication of multilayer solution-processed OLED devices free of layer dissolution problems.

Examples of crosslinkable polymers can be found in, for example, published US patent application 2005-0184287 and published PCT application WO 2005/052027.

In some embodiments, the hole transport layer comprises a polymer which is a copolymer of 9,9-dialkylfluorene and triphenylamine. In some embodiments, the polymer is a copolymer of 9,9-dialkylfluorene and 4,4′-bis(diphenylamino)biphenyl. In some embodiments, the polymer is a copolymer of 9,9-dialkylfluorene and TPB. In some embodiments, the polymer is a copolymer of 9,9-dialkylfluorene and NPB. In some embodiments, the copolymer is made from a third comonomer selected from (vinylphenyl)diphenylamine and 9,9-distyrylfluorene or 9,9-di(vinylbenzyl)fluorene.

Depending upon the application of the device, the electroactive layer 140 can be a light-emitting layer that is activated by an applied voltage (such as in a light-emitting diode or light-emitting electrochemical cell), a layer of material that responds to radiant energy and generates a signal with or without an applied bias voltage (such as in a photodetector). In one embodiment, the electroactive material is an organic electroluminescent (“EL”) material, Any EL material can be used in the devices, including, but not limited to, small molecule organic fluorescent compounds, fluorescent and phosphorescent metal complexes, conjugated polymers, and mixtures thereof. Examples of fluorescent compounds include, but are not limited to, pyrene, perylene, rubrene, coumarin, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Electroluminescent emissive layers comprising a charge carrying host material and a metal complex have been described by Thompson et al., in U.S. Pat. No. 6,303,238, and by Burrows and Thompson in published PCT applications WO 00/70655 and WO 01/41512. Examples of conjugated polymers include, but are not limited to poly(phenylenevinylenes), polyfluorenes, poly(spirobifluorenes), polythiophenes, poly(p-phenylenes), copolymers thereof, and mixtures thereof.

Optional layer 150 can function both to facilitate electron injection/transport, and can also serve as a confinement layer to prevent quenching reactions at layer interfaces. More specifically, layer 140 may promote electron mobility and reduce the likelihood of a quenching reaction if layers 140 and 160 would otherwise be in direct contact. Examples of materials for optional layer 150 include, but are not limited to, metal chelated oxinoid compounds, such as bis(2-methyl-8-quinolinolato)(para-phenyl-phenolato)aluminum(III) (BAIQ), tris(8-hydroxyquinolato)aluminum (Alq₃), and tetrakis(8-hydroxyquinolinato)zirconium(Zrq4); azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthroline derivatives such as 9,10-diphenylphenanthroline (DPA) and 2,9-dimethyl-4,7-diphenyl-1,10-phenanthroline (DDPA); and any one or more combinations thereof. Alternatively, optional layer 150 may be inorganic and comprise BaO, LiF, Li₂O, or the like.

The cathode layer 160 is an electrode that is particularly efficient for injecting electrons or negative charge carriers. The cathode layer 160 can be any metal or nonmetal having a lower work function than the first electrical contact layer (in this case, the anode layer 110). As used herein, the term “lower work function” is intended to mean a material having a work function no greater than about 4.4 eV. As used herein, “higher work function” is intended to mean a material having a work function of at least approximately 4.4 eV.

Materials for the cathode layer can be selected from alkali metals of Group 1 (e.g., Li, Na, K, Rb, Cs,), the Group 2 metals (e.g., Mg, Ca, Ba, or the like), the Group 12 metals, the lanthanides (e.g., Ce, Sm, Eu, or the like), and the actinides (e.g., Th, U, or the like). Materials such as aluminum, indium, yttrium, and combinations thereof, may also be used. Specific non-limiting examples of materials for the cathode layer 160 include, but are not limited to, barium, lithium, cerium, cesium, europium, rubidium, yttrium, magnesium, samarium, and alloys and combinations thereof.

The cathode layer 160 is usually formed by a chemical or physical vapor deposition process. In some embodiments, the cathode layer will be patterned, as discussed above in reference to the anode layer 110.

Other layers in the device can be made of any materials which are known to be useful in such layers upon consideration of the function to be served by such layers.

In some embodiments, an encapsulation layer (not shown) is deposited over the contact layer 160 to prevent entry of undesirable components, such as water and oxygen, into the device 100. Such components can have a deleterious effect on the organic layer 140. In one embodiment, the encapsulation layer is a barrier layer or film. In one embodiment, the encapsulation layer is a glass lid.

Though not depicted, it is understood that the device 100 may comprise additional layers. Other layers that are known in the art or otherwise may be used. In addition, any of the above-described layers may comprise two or more sub-layers or may form a laminar structure. Alternatively, some or all the layers may be treated, especially surface treated, to increase charge carrier transport efficiency or other physical properties of the devices. The choice of materials for each of the component layers is preferably determined by balancing the goals of providing a device with high device efficiency with device operational lifetime considerations, fabrication time and complexity factors and other considerations appreciated by persons skilled in the art. It will be appreciated that determining optimal components, component configurations, and compositional identities would be routine to those of ordinary skill of in the art.

In one embodiment, the different layers have the following range of thicknesses: anode 110, 500-5000 Å, in one embodiment 1000-2000 Å; buffer layer 120, 50-2000 Å, in one embodiment 200-1000 Å; optional hole transport layer 130, 50-2000 Å, in one embodiment 200-1000 Å; photoactive layer 140, 10-2000 Å, in one embodiment 100-1000 Å; optional electron transport layer 150, 50-2000 Å, in one embodiment 100-1000 Å; cathode 160, 200-10000 Å, in one embodiment 300-5000 Å. The location of the electron-hole recombination zone in the device, and thus the emission spectrum of the device, can be affected by the relative thickness of each layer. Thus the thickness of the electron-transport layer should be chosen so that the electron-hole recombination zone is in the light-emitting layer. The desired ratio of layer thicknesses will depend on the exact nature of the materials used.

In operation, a voltage from an appropriate power supply (not depicted) is applied to the device 100. Current therefore passes across the layers of the device 100. Electrons enter the organic polymer layer, releasing photons. In some OLEDs, called active matrix OLED displays, individual deposits of photoactive organic films may be independently excited by the passage of current, leading to individual pixels of light emission. In some OLEDs, called passive matrix OLED displays, deposits of photoactive organic films may be excited by rows and columns of electrical contact layers.

### EXAMPLES

The concepts described herein will be further described in the following examples, which do not limit the scope of the invention described in the claims.

### VOC Analysis Method

A polymer dispersion is diluted with a suitable solvent, usually 0.05N sodium hydroxide, and analyzed by gas chromatography (GC). The amount of the polymer solution and the solvent are analytically weighed. The diluted sample is injected into a glass insert attached to a GC column. The polymer is deposited on the sides and glass wool of the glass insert; the volatile organic components pass onto the column. The sodium hydroxide reacts with the sulfonic acid group of the polymer dispersion and inhibits its catalytic effect. Volatile components (water, methanol, ethanol, 2-propanol, and 1-propanol) are separated on the column resulting in peaks with area percents corresponding to the amount of volatile components present. The peaks are normalized to 100% of the volatile material present and a calculation made of each volatile component. The water added as dilute sodium hydroxide can be back calculated and therefore the amount of water in the original polymer solution, if any, can be calculated. Note that organic volatile components shown in the example do not include water. The detection limit by this method is at least approximately 0.01% by weight.

### Comparative Example A

This comparative example illustrates the polymerization of 3,4-ethylenedioxythiophene (EDOT) using as FFAP a copolymer of tetrafluoroethylene (“TFE”) and 3,6-dioxa-4-methyl-7-octenesulfonic acid (“PSEPVE), which contains small percentage of VOC and therefore is not ultra-pure. The copolymer is abbreviated as p-(TFE/PSEPVE).

The p-(TFE/PSEPVE) had an acid equivalent weight (EW) of 1050 g per one sulfonic acid. It contained 11.4% (w/w) polymer in water and was analyzed to have 0.08% (w/w) volatile organic volatile compounds according to the VOC analysis method. The VOC was primarily propanol.

3,4-ethylenedioxythiophene (“EDOT”) monomers were reacted with the p-(TFE/PSEPVE) dispersion as described in published U.S. patent application 2004-02542970. The polymerization ingredients had the following mole ratios: p-(TFE/PSEPVE)/EDOT: 2.75, Na₂S₂O₈/EDOT: 1.25, Fe₂(SO₄)₃/EDOT: 0.033, HCl/EDOT:0.5. Solid content was calculated to be 4% (w/w).

The polymerization was quenched by adding 15 g Lewatit Monoplus S100, 15 g Amberjet 4400 (OH), and 20 g n-propanol. Lewatit Monoplus S100 is a trade name for sodium sulfonate of crosslinked polystyrene from Bayer, Pittsburgh, Pa. Amberjet 4400 (OH) is an anion exchange resin from Rohm and Haas Co., Philadelphia, Pa. Prior to the use, Monoplus S-100 was washed with water until there was no color in the water wash. Amberjet 4400 was rinsed multiple times with a 32% n-propanol (in DI water). The final dispersion had a pH of 5.7. The conductivity of spin-coated films, baked at 130° C. in air for 10 minutes, was measured to be less than 1×10⁻⁹ S/cm at room temperature.

### Comparative Example B

This example illustrates the polymerization of EDOT using as FFAP a p-(TFE/PSEPVE), which contains small percentage of VOC, and therefore is not ultrapure.

The p-(TFE/PSEPVE) copolymer had an acid equivalent weight (EW) of 999 g per one sulfonic acid. It contained 12% (w/w) copolymer in water and was analyzed to have 0.3% (w/w) organic volatile components according to the VOC analysis method. The VOC was primarily propanol.

EDOT monomer was polymerized with the p-(TFE/PSEPVE) dispersion according to the same procedure and using the same mole ratio of each component and same amount of the ingredients as described in Comparative Example A. As in Comparative Example A, the polymerization was quenched and worked up to obtain the final dispersion. It had a pH of 4.22. The conductivity of spin-coated films, baked at 130° C. in air for 10 minutes, was measured to be less than 1×10⁻⁹ S/cm at room temperature.

### Example 1

This example illustrates the polymerization of EDOT with an ultra-pure aqueous dispersion of p-(TFE/PSEPVE) which contains no detectable VOC.

The aqueous dispersion of p-(TFE/PSEPVE) was made using a procedure similar to the procedure in U.S. Pat. No. 6,150,426, Example 1, Part, except that the temperature was approximately 270° C. The p-(TFE/PSEPVE) having an EW of 1050 was converted to an aqueous dispersion purely from the use of ultra-pure water. This dispersion conversion method is designed to eliminate any trace of organic volatile components, which was confirmed from the VOC analysis. No VOC was detectable from the VOC analysis. The aqueous dispersion had 25% (w/w) p-(TFE/PSEPVE) in water and was diluted to 12% with deionized water prior to the use for polymerization with EDOT.

The polymerization was carried out according to the same procedure and using to the same mole ratio of each component and same amount of the ingredients as described in Comparative Example A. As in Comparative Example A, the polymerization was quenched and worked up to obtain the final dispersion. It had a pH of 4.15. The conductivity of spin-coated films, baked at 130° C. in air for 10 minutes, was measured to be 2.1×10⁻² S/cm at room temperature. This conductivity is much higher than those shown in Comparative Examples A and B. The results are summarized in Table 1.

### Example 2

Example 1 was repeated using an ultra-pure p-(TFE/PSEPVE) sample having an EW of 950 as an 11.5% (w/w) dispersion in water. The resulting PEDOT/p-(TFE/PSEPVE) conductive polymer had a pH of 4.72. The conductivity of spin-coated films, baked at 130° C. in air for 10 minutes, was measured to be 2.4×10⁻³ S/cm at room temperature. This conductivity is much higher than that shown in Comparative Examples A and B. The results are summarized in Table 1.

### Comparative Example C

This example illustrates effect of the addition of n-propanol to an ultra-pure aqueous dispersion of an FFAP.

To the 12% aqueous dispersion of p-(TFE/PSEPVE) from Example 1 was added n-propanol to the level of 0.08% (w/w). The polymerization of EDOT was carried out according to the same procedure using the same mole ratio of each component and same amount of the ingredients as in Example 1. The polymerization was quenched and worked up to obtain the final dispersion. It had a pH of 3.91. The conductivity of spin-coated films, baked at 130° C. in air for 10 minutes, was measured to be 3.7×10⁻⁵ S/cm at room temperature. This conductivity is much lower than that shown in Example 1. The results are summarized in Table 1, which illustrates effect of organic volatile components on the conductivity of PEDOT/p-(TVE/PSEPVE).

### Comparative Example D

This example illustrates effect of the addition of diethylether to an ultra-pure aqueous dispersion of an FFAP.

Comparative Example C was repeated except that 0.3% diethylether was added instead of n-propanol, to the level of 0.3% (w/w). The final dispersion had a pH of 4.22. The conductivity of spin-coated films, baked at 130° C. in air for 10 minutes, was measured to be 6.5×10⁻⁵ S/cm at room temperature. This conductivity is much lower than that shown in Example 1. The results are summarized in Table 1, which again illustrates effect of organic volatile components on conductivity of PEDOT/p-(TVE/PSEPVE).

### Comparative Example E

This example also illustrates effect of a higher % of n-propanol added to an ultra-pure aqueous dispersion of the p-(TFE/PSEPVE).

Comparative Example C was repeated, except that the level of n-propanol was 0.3% (w/w). The final dispersion had a pH of 3.91. The conductivity of spin-coated films, baked at 130° C. in air for 10 minutes, was measured to be <1×10⁻⁹ S/cm at room temperature. This conductivity is much lower than that shown in Example 1. The results are summarized in Table 1, which again illustrates effect of organic volatile components on conductivity of PEDOT/p-(TVE/PSEPVE).

TABLE 1
Effect of VOC on conductivity of PEDOT/p-(TFE/PSEPVE)

| Example | VOC % | Conductivity (S/cm) |
|---|---|---|
| Comp. | 0.08% propanol in | <1 × 10⁻⁹ |
| Example A | p-(TFE/PSEPVE) | |
| Comp. | 0.3% propanol in | <1 × 10⁻⁹ |
| Example B | p-(TFE/PSEPVE) | |
| Example 1 | p-(TFE/PSEPVE) with | 2.1 × 10⁻² |
| | 0% VOC | |
| Example 2 | p-(TFE/PSEPVE) with | 2.4 × 10⁻³ |
| | 0% VOC | |
| Comp. | Example 1 | 3.7 × 10⁻⁵ |
| Example C | p-(TFE/PSEPVE) with | |
| | 0.08% n-propanol added | |
| Comp. | Example 1 | 6.5 × 10⁻⁵ |
| Example D | p-(TFE/PSEPVE) with | |
| | 0.3% diethylether added | |
| Comp. | Example 1 | <1 × 10⁻⁹ |
| Example E | p-(TFE/PSEPVE) with | |
| | 0.3% n-propanol added | |

### Example 3

This example illustrates the polymerization of pyrrole (“Py”) with an aqueous dispersion of ultra-pure p-(TFE/PSEPVE).

In this example, the ultra-pure aqueous dispersion of p-(TFE/PSEPVE) from Example 2 was used.

Py monomers were reacted with the ultra-pure p-(TFE/PSEPVE) dispersion as described in U.S. patent application 2005-0205860. The polymerization ingredients have the following mole ratios: p-(TFE/PSEPVE)/Pyrrole: 2.5, Na₂S₂O₈/pyrrole: 0.9, Fe₂(SO₄)₃/pyrrole: 0.11. Solid content was calculated to be 8% (w/w). The resulting product is abbreviated as Ppy/p-(TFE/PSEPVE), where Ppy stands for polypyrrole.

After one hour of reaction time, 35 og g of each Dowex M31, and Dowex M43 ion exchange resins, and 350 g de-ionized water were added to the reaction mixture with stirring for another 4 hours at 120 RPM. The ion-exchange resins were finally filtered from the dispersion through VWR 417 filter paper. The conductivity of spin-coated films baked at 130° C. in air for 10 minutes was 1.3×10⁻² S/cm at room temperature.

### Comparative Example F

This example also illustrates the effect of 0.1% n-propanol added to an ultra-pure aqueous dispersion of p-(TFE/PSEPVE).

In this example, n-propanol was added to the 12% ultra-pure aqueous dispersion of p-(TFE/PSEPVE) described in Example 3 to the level of 0.1% (w/w). The polymerization of pyrrole was carried out as described in Example 3. As done in Example 3, the polymerization was quenched and worked up to obtain the final dispersion. The conductivity of spin-coated films, baked at 130° C. in air for 10 minutes, was measured to be 1.3×10⁻³ S/cm at room temperature. This conductivity was lower than that shown in Example 3. The results are summarized in Table 2, which illustrates effect of organic volatile components on conductivity of Ppy/p-(TFE/PSEPVE).

### Comparative Example G

This example illustrates effect of the effect of 0.5% n-propanol added to an ultra-pure aqueous dispersion of p-(TFE/PSEPVE).

In this example, n-propanol was added to the 12% aqueous dispersion of p-(TFE/PSEPVE) described in Example 3 to the level of 0.5% (w/w). The polymerization of pyrrole was carried out as described in Example 3. As done in Example 3, the polymerization was quenched and worked up to obtain the final dispersion. The conductivity of spin-coated films, baked at 130° C. in air for 10 minutes, was measured to be 3.1×10⁻⁴ S/cm at room temperature. This conductivity is lower than that shown in Example 3. It is also lower than that in Comparative Example F in which the p-(TFE/PSEPVE) dispersion has a lower % n-propanol. The results are summarized in Table 2, which illustrates effect of organic volatile components on the conductivity of Ppy/p-(TFE/PSEPVE).

### Comparative Example H

This example also illustrates the effect of 1.0% n-propanol added to an ultra-pure aqueous dispersion of p-(TFE/PSEPVE).

In this example, n-propanol was added to the 12% ultra-pure aqueous dispersion of p-(TFE/PSEPVE) described in Example 3 to the level of 1.0% (w/w). The polymerization of pyrrole was carried out as described in Example 3. As done in Example 3, the polymerization was quenched and worked up to obtain the final dispersion. The conductivity of spin-coated films, baked at 130° C. in air for 10 minutes, was measured to be 4.8×10⁻⁵ S/cm at room temperature. This conductivity is lower than that shown in Example 3. It is lower than those of Comparative Examples F and G. The results are summarized in Table 2, which illustrates the effect of organic volatile components on the conductivity of Ppy/p-(TFE/PSEPVE).

TABLE 2
Effect of VOC on Conductivity of Ppy/p-(TFE/PSEPVE)

| Example | VOC % | Conductivity (S/cm) |
|---|---|---|
| Example 3 | 0% volatile organic components | 1.3 × 10⁻² |
| Comp. | Example 3 | 1.3 × 10⁻³ |
| Example F | p-(TFE/PSEPVE) with | |
| | 0.1% n-propanol added | |
| Comp. | Example 1 | 3.1 × 10⁻⁴ |
| Example G | p-(TFE/PSEPVE) with | |
| | 0.5% diethylether added | |
| Comp. | Example 1 | 4.8 × 10⁻⁵ |
| Example H | p-(TFE/PSEPVE) with | |
| | 0.1% n-propanol added | |

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. The use of numerical values in the various ranges specified herein is stated as approximations as though the minimum and maximum values within the stated ranges were both being preceded by the word “about.” In this manner slight variations above and below the stated ranges can be used to achieve substantially the same results as values within the ranges. Also, the disclosure of these ranges is intended as a continuous range including every value between the minimum and maximum average values including fractional values that can result when some of components of one value are mixed with those of different value. Moreover, when broader and narrower ranges are disclosed, it is within the contemplation of this invention to match a minimum value from one range with a maximum value from another range and vice versa.

1-18. (canceled)

19. A method of an aqueous dispersion of a conductive polymer composition, said method comprising forming a reaction mixture by combining water, at least one precursor monomer for the conductive polymer, at least one ultra-pure fully-fluorinated acid polymer, and an oxidizing agent, in any order, and further provided that at least a portion of the ultra-pure fully-fluorinated acid polymer is present when at least one of the precursor monomer when the oxidizing agent is added.

20. The method according to claim 19, wherein the ultra-pure fully-fluorinated acid polymer is w selected from the group consisting of carboxylic acid, sulfonic acid, sulfonimide, phosphoric acid, phosphonic acid, and combinations thereof.

21. The conductive composition of claim 19, wherein the fully-fluorinated acid polymer comprises acidic groups selected from the group consisting of sulfonic acid and sulfonamide.

22. The conductive composition of claim 19, wherein the fully-fluorinated acid polymer comprises a perfluorinated olefin backbone with pendant perfluorinated alkyl sulfonate, perfluorinated ether sulfonate, perfluorinated ester sulfonate, or perfluorinated ether sulfonimide groups.

23. The method according to claim 19, wherein a mixture of water and at least one precursor monomer is formed, in a concentration typically in the range of about 0.5% by weight to about 4.0% by weight total precursor monomer.

24. The method according to claim 19, wherein the aqueous polymerization mixture may include a polymerization catalyst.is carried out in the presence of at least one co-acid.

25. The method according to claim 19, wherein the molar ratio of the oxidizer to total precursor monomer is in the range of 0.1 to 2.0.

26. The method according to claim 19, wherein the molar ratio of the oxidizer to total precursor monomer is in the range of 0.4 to 1.5.

27. The method according to claim 19, wherein the molar ratio of the ultra-pure fully-fluorinated acid polymer to total precursor monomer is in the range of 0.3 to 10.

28. The method according to claim 19, wherein the molar ratio of the ultra-pure fully-fluorinated acid polymer to total precursor monomer is in the range of 1 to 7.

29. The method according to claim 19, wherein the overall solid content is in the range of 0.5% to 15% in weight percentage.

30. The method according to claim 19, wherein the polymerization is carried out at a reaction temperature in the range of from 4° C. to 50° C.

31. An electronic device comprising, in order an anode, a buffer layer, a photoactive layer, and a cathode, wherein the buffer layer comprises the electrically conductive polymer made in accordance with claim 19.
